(19) United States
(12) Patent Application Publication
(10) Pub. No.: US 2016/0336499 A1
(43) Pub. Date: Nov. 17, 2016

(54) ELECTRONIC DEVICE AND METHOD OF MAKING THE SAME

(71) Applicant: Taiwan Green Point Enterprises Co., Ltd., Taichung City (TW)

(72) Inventors: Pen-Yi LIAO, Taichung City (TW); Chih-Hao CHEN, Taichung City (TW); Hui-Ching CHUANG, Taichung City (TW); Ai-Ling LIN, Taichung City (TW)

(73) Assignee: Taiwan Green Point Enterprises Co., Ltd., Taichung City (TW)

(21) Appl. No.: 15/150,925

(22) Filed: May 10, 2016

(30) Foreign Application Priority Data
May 12, 2015 (TW) 104115032

(51) Int. Cl. H01L 33/64; H01L 33/62

(52) U.S. Cl. CPC H01L 33/64; H01L 33/62; H01L 2933/0066; H01L 2933/0075

(57) ABSTRACT

A method of making an electronic device includes: providing a base unit including a metal substrate, an insulating layer disposed on the metal substrate, and a first circuit unit disposed on the insulating layer; and laser ablating the first circuit unit, the insulating layer and the metal substrate in such a manner that a hole defined by a hole-defining wall is formed to expose the metal substrate, and that an interconnecting layer is formed on the hole-defining wall during laser ablation of the metal substrate.

### CROSS-REFERENCE TO RELATED APPLICATION

This application claims priority of Taiwanese Patent Application No. 104115032, filed on May 12, 2015, which is incorporated by reference as if fully set forth.

### FIELD

Embodiments of the present disclosure generally relate to an electronic device and a method of making the same, and more particularly to an electronic device with excellent heat dissipating efficiency and a time and cost effective method of making the same.

### BACKGROUND

Many electronic devices include multilayer electronic components, in which vias are commonly formed to extend through and electrically connect the multilayer electronic components. Typically, the vias are manufactured by forming holes extending through the respective components, and then respectively forming conductive layers in the holes, by, e.g., film coating, electroplating or chemical plating. However, the aforesaid processes of forming the vias are relatively time and cost consuming.

Moreover, electronic devices may generate a large amount of heat during operation, and temperatures of the electronic devices may rapidly increase which would adversely affect the properties of the electronic devices. Thus, heat dissipation has become one of the major concerns for electronic devices.

### SUMMARY

Certain embodiments of the disclosure provide a method of making an electronic device that may alleviate at least one of the drawbacks of the prior art. The method may include: providing a base unit that includes a metal substrate, an insulating layer disposed on the metal substrate, and a first circuit unit disposed on the insulating layer; and laser ablating the first circuit unit, the insulating layer and the metal substrate in such a manner that a hole defined by a hole-defining wall is formed to extend through the first circuit unit and the insulating layer and to terminate at and expose the metal substrate, and that an interconnecting layer is formed on the hole-defining wall using a metal material of the metal substrate that is ablated during laser ablation of the metal substrate, the interconnecting layer extending from the metal substrate to the first circuit unit.

In certain embodiments of the disclosure, an electronic device may be provided. The electronic device may include: a base unit that includes a metal substrate, a circuit unit and an insulating layer disposed between the metal substrate and the circuit unit, and that has a hole formed by laser ablation, the hole extending through the circuit unit and the insulating layer and terminating at and exposing the metal substrate; and an interconnecting layer which is formed on the hole-defining wall using a metal material of the metal substrate that is ablated during laser ablation of the metal substrate, the interconnecting layer extending from the metal substrate to the circuit unit.

### BRIEF DESCRIPTION OF THE DRAWINGS

Other features and advantages of the disclosure will become apparent in the following detailed description of the embodiment (s) with reference to the accompanying drawings, of which:

FIG. 1 is a flowchart illustrating a first embodiment of a method of making an electronic device according to the disclosure;

FIGS. 2 to 5 are schematic views illustrating consecutive steps of the method of FIG. 1;

FIG. 6 is a schematic view illustrating an electronic device made by the method of FIG. 1;

FIG. 7 is a schematic view illustrating an electronic device made by a variation of the first embodiment;

FIG. 8 is a flow chart illustrating a second embodiment of a method of making an electronic device according to the disclosure;

FIGS. 9 to 12 are schematic views illustrating consecutive steps of the method of FIG. 8;

FIG. 13 is an electron microscope image of an interconnecting layer formed by the method of FIG. 8; and

FIG. 14 is a schematic view illustrating an electronic device made by the method of FIG. 8.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

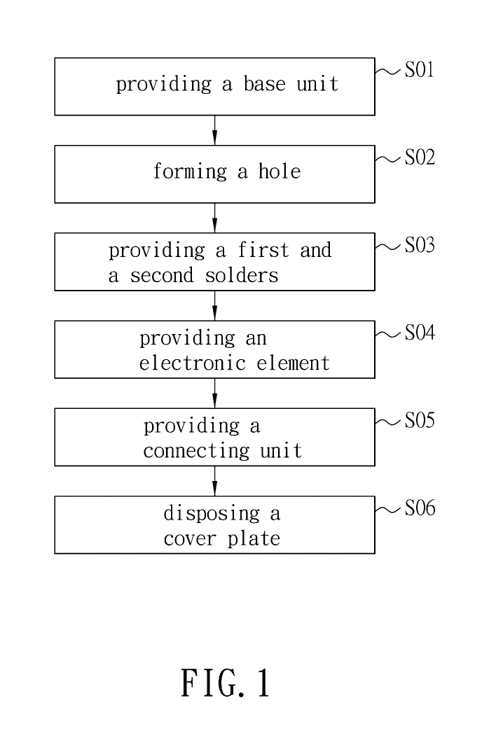

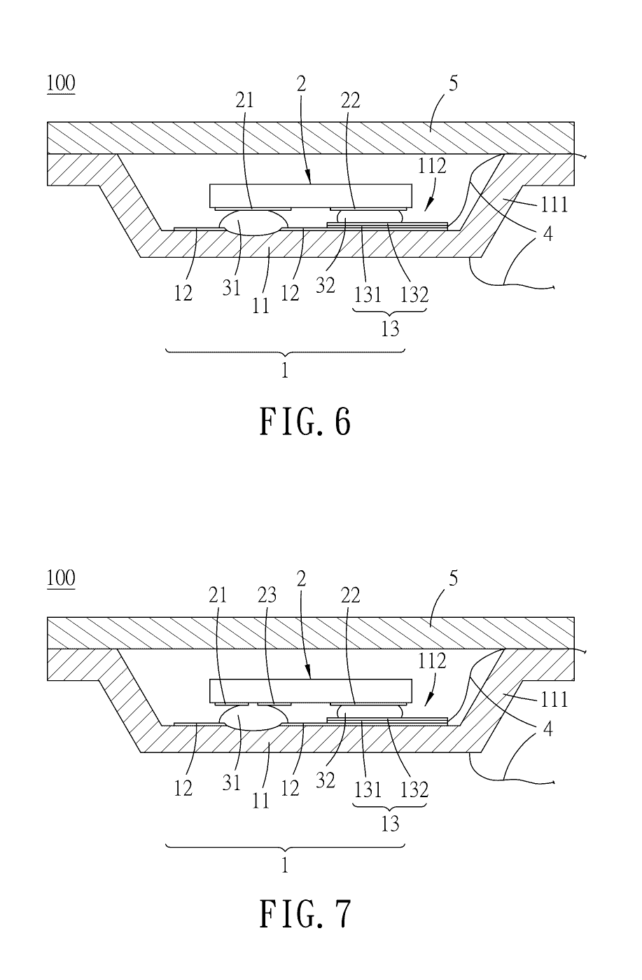

Referring to FIG. 1, a first embodiment of a method for making an electronic device 100 (see FIG. 6) according to the disclosure includes the following consecutive steps S01 to S06.

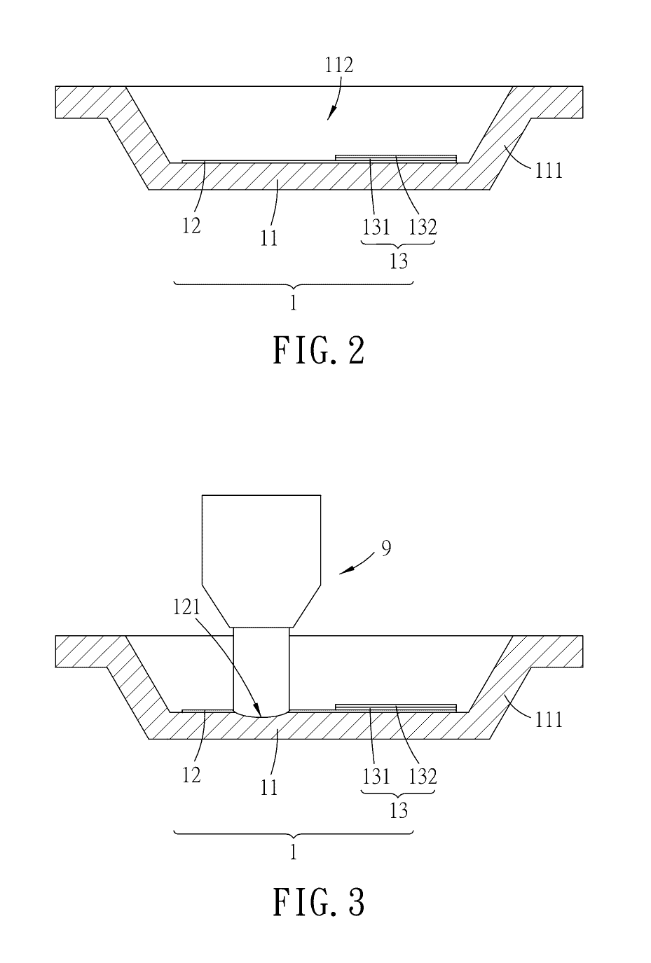

Step S01: providing a base unit 1 that includes a metal substrate 11, an insulating layer 12 disposed on the metal substrate 11, and a circuit unit 13 (see FIG. 2). The metal substrate 11 has a peripheral portion 111 that is upwardly bent so that the metal substrate 11 is formed with a receiving space 112. The insulating layer 12 and the circuit unit 13 are disposed within the receiving space 112. In certain embodiments, the circuit unit 13 is manufactured using chemical plating techniques, so that the circuit unit 13 includes an active layer 131 that is formed on the insulating layer 12 and that contains active metal, and an electrolessly deposited metal layer 132 formed on the active layer 131. In certain embodiments, the circuit unit 13 may further include an electronically deposited metal layer (not shown) formed on the electrolessly deposited metal layer 132 by electroplating techniques. In certain embodiments, the circuit unit 13 may be formed using other well known techniques.

Step S02: forming a hole 121 in the insulating layer 12 (see FIG. 3). The hole 121 is spaced apart from the circuit unit 13 and exposes the metal substrate 11. In this embodiment, the hole 121 is formed using a laser 9. In certain embodiments, the hole 121 may be formed using drilling techniques, such as mechanical drilling, but is not limited thereto according to the present disclosure.

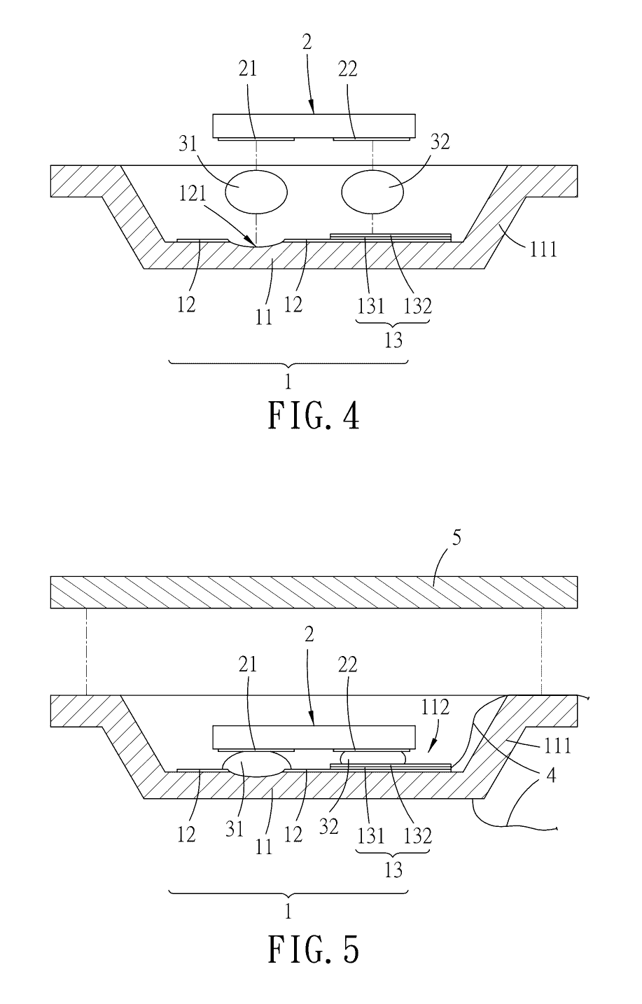

Step S03: providing a first solder 31 in the hole 121 of the insulating layer 12 such that the first solder 31 contacts the metal substrate 11, and a second solder 32 on the circuit unit 13 (see FIGS. 4 and 5).

Step S04: providing an electronic element 2 on the base unit 1 (see FIGS. 4 and 5). To be specific, the electronic element 2 has a first electrode 21 and a second electrode 22, which are respectively disposed on the first and second solders 31, 32, such that the first electrode 21 is electrically connected to the metal substrate 11 through the first solder 31, and the second electrode 22 is electrically connected to the circuit unit 13 through the second solder 32.

Step S05: providing a connecting unit 4 electrically connected to the circuit unit 13 and the metal substrate 11 (see FIG. 5). The connecting unit 4 can respectively and electrically connect the circuit unit 13 and the metal substrate 11 to two terminals of a power supply (not shown), so that the electronic device 100 can receive an external power source through the connecting unit 4.

Step S06: disposing a cover plate 5 on the peripheral portion 111 of the metal substrate 11 to enclose the receiving space 112 of the metal substrate 11, so as to obtain the electronic device 100 (see FIGS. 5 and 6). In certain embodiments, the cover plate 5 may be dispensed with, and the Step S06 may be omitted.

In this embodiment, forming the hole 121 in the insulating layer 12 and disposing the first solder 31 in the hole 121 to contact the metal substrate allows the metal substrate 11 and the circuit unit 13 to be electrically connected.

In certain embodiments, the electronic device 100 may be a backlight module, and the metal substrate 11 may be shaped as a casing having the receiving space 112 in which the electronic element 2 and the circuit unit 13 are disposed. The electronic element 2 may be a light source of the backlight module. The cover plate 5 may be an optical element, such as a diffusion sheet, brightening film, etc.

In certain embodiments, the electronic element 2 may be a light emitting diode, in which the first and second electrodes 21, 22 are respectively a negative electrode and a positive electrode that exhibits heat conducting property. In such embodiment, the circuit unit 13 and the metal substrate 11 are electrically connected to the positive and negative terminals of the power supply, respectively. As such, the first and the second electrodes 21, 22 can directly conduct the heat to the metal substrate 11 and the circuit unit 13 via the first and second solders 31, 32, respectively. Since the first electrode 21 exhibits heat conducting property, the heat can be directly conducted from the light emitting diode to the metal substrate 11 which has high thermal conductivity, and then dissipated into the ambient environment, thereby increasing the heat dissipation efficiency of the electronic device 100.

It should be noted that, in the first embodiment, the electronic device 100 includes single electronic element 2, but the electronic device 100 may have a plurality of the electronic elements 2 in other embodiments. For example, when the electronic device 100 is used as a backlight module, the electronic device 100 may have a plurality of electronic elements 2 serving as light sources.

FIG. 7 illustrates an electronic device 100 made by a variation of the first embodiment. In FIG. 7, the electronic element 2 further includes a thermal pad 23 for heat conduction. In Step S04 of the variation of the first embodiment, the thermal pad 23 is connected to the first solder 31, so as to more greatly improve the heat dissipation efficiency of the electronic device 100.

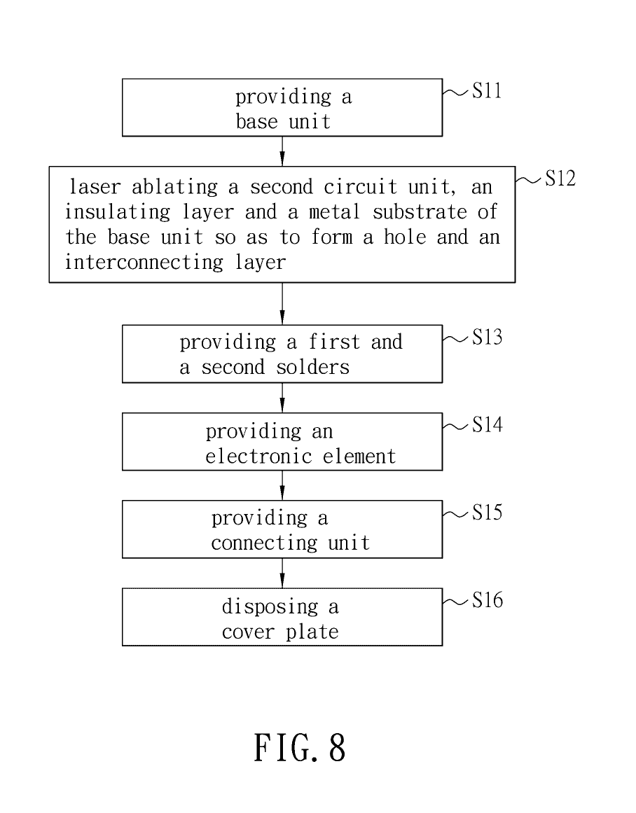

Referring to FIG. 8, the disclosure also provides a second embodiment of a method of making the electronic device 100, which includes the following consecutive steps S11 to S16.

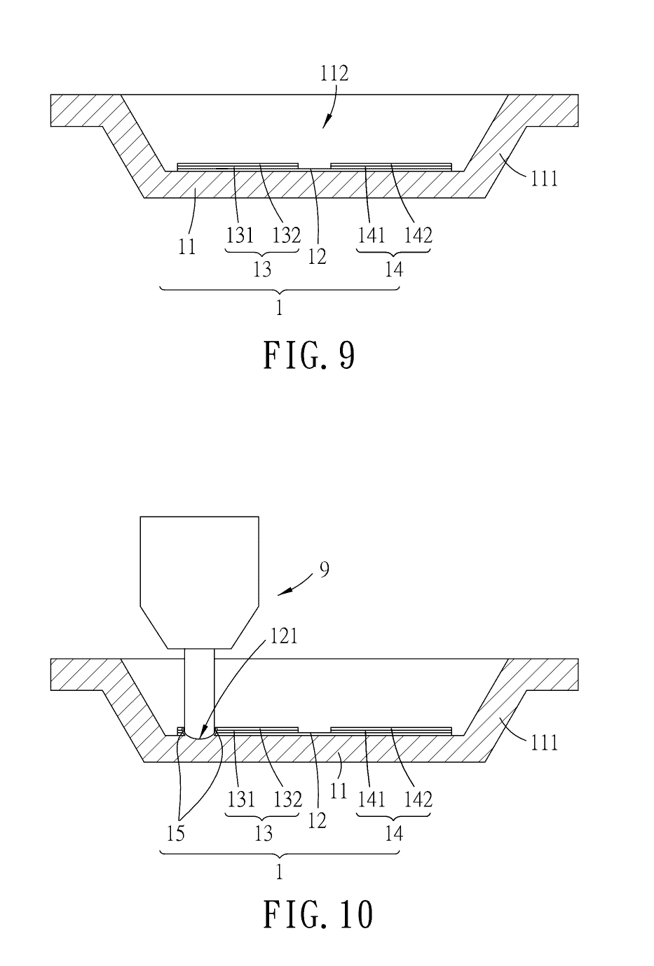

Step S11: providing a base unit 1 that includes a metal substrate 11, an insulating layer 12 disposed on the metal substrate 11, and first and second circuit units 13, 14 separately disposed on the insulating layer 12 (see FIG. 9). Similar to the first embodiment, the first and second circuit units 13, 14 may be manufactured using chemical plating techniques, so that each of the first and second circuit units 13, includes an active layer 131, 141 formed on the insulating layer 12 and the electrolessly deposited metal layer 132, 142 formed on the active layer 131, 141. In this embodiment, the metal substrate 11 has a peripheral portion 111 that is upwardly bent so that the metal substrate 11 is formed with a receiving space 112. The insulating layer 12 and the first and second circuit units 13, 14 are disposed within the receiving space 112.

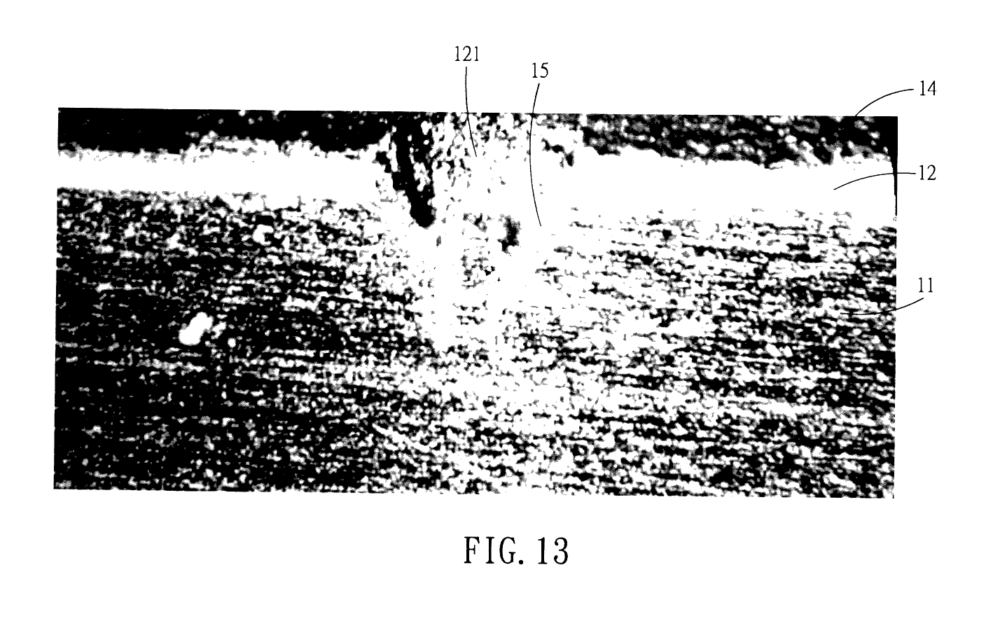

Step S12: laser ablating the first circuit unit 13, the insulating layer 12 and the metal substrate 11 using a laser 9 in such a manner that a hole 121 defined by a hole-defining wall is formed to extend through the first circuit unit 13 and the insulating layer 12 and to terminate at and expose the metal substrate 11, and that an interconnecting layer 15 is formed on the hole-defining wall using a metal material of the metal substrate 11 that is ablated during laser ablation of the metal substrate 11 (see FIGS. 10 and 13). The interconnecting layer 15 extends from the metal substrate 11 to the first circuit unit 13, so as to electrically connect the first circuit unit 13 to the metal substrate 11. In this embodiment, the hole-defining wall has structural characteristics indicative of the hole being formed by laser ablation. In this embodiment, the laser ablation is conducted under a laser power of about 12 W, a laser speed of about 600 mm per second and a laser wavelength of about 1064 nm.

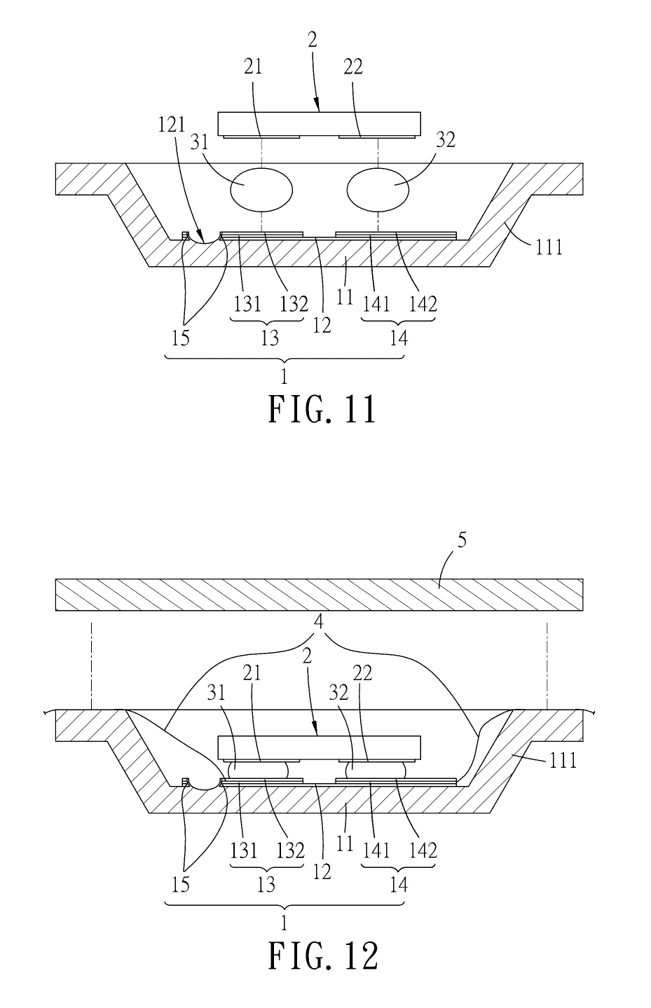

Step S13: providing a first solder 31 on the first circuit unit 13 and a second solder 32 on the second circuit unit 14 (see FIG. 11).

Step S14: providing an electronic element 2 that has a first electrode 21 and a second electrode 22, and then respectively disposing the first electrode 21 and the second electrode 22 of the electronic element 2 on the first and second solders 31, 32, such that the first electrode 21 is electrically connected to the first circuit unit 13 through the first solder 31, and the second electrode 22 is electrically connected to the second circuit unit 14 through the second solder 32 (see FIGS. 11 and 12).

Step S15: providing a connecting unit 4 electrically connected to the first and second circuit units 13, 14 (see FIG. 12). The connecting unit 4 can respectively and electrically connect the first and second circuit units 13, 14 to two terminals of a power supply (not shown), so that the electronic device 100 can receive an external power source through the connecting unit 4.

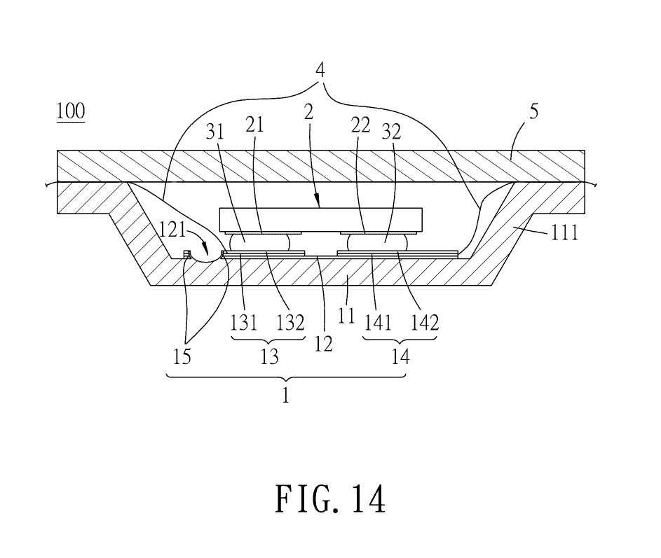

Step S16: disposing a cover plate 5 on the peripheral portion 111 of the metal substrate 11 to enclose the receiving space 112 of the metal substrate 11, so as to obtain the electronic device 100 (see FIGS. 12 and 14). In certain embodiments, the cover plate 5 may be dispensed with, and the Step S16 may be omitted.

In this embodiment, the metal material of the metal substrate 11 produced during the laser ablation of the metal substrate 11 can be deposited on the hole-defining wall of the hole 121, so that the interconnecting layer 15 can be formed during forming of the hole 121. Thus, the method is relatively simple compared to the conventional method (in which a conductive layer is required to be formed on a hole using film coating, electroplating or chemical plating after the hole is formed). Moreover, similar to the first embodiment, the heat from the electronic element 2 (such as a light emitting diode) can be effectively transmitted to the first circuit unit 13 through the first solder 31, and to the metal substrate 11 (which has high thermal conductivity) through the interconnecting layer 15, and finally dissipated into the ambient environment.

In summary, by forming the interconnecting layer 15 during laser ablation or directly disposing the first solder 31 in the hole 121, the metal substrate 11 can be electrically connected to the electronic element 2, thereby simplifying the manufacturing process and lowering the manufacturing cost. Moreover, the heat from the electronic element 2 can be effectively dissipated into the ambient environment through the metal substrate 11, so that the electronic device 100 of the present disclosure may exhibit excellent heat dissipating performance.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A method of making an electronic device, comprising the steps of:
providing a base unit that includes a metal substrate, an insulating layer disposed on the metal substrate, and a first circuit unit disposed on the insulating layer; and
laser ablating the first circuit unit, the insulating layer and the metal substrate in such a manner that a hole defined by a hole-defining wall is formed to extend through the first circuit unit and the insulating layer and to terminate at and expose the metal substrate, and that an interconnecting layer is formed on the hole-defining wall using a metal material of the metal substrate that is ablated during laser ablation of the metal substrate, the interconnecting layer extending from the metal substrate to the first circuit unit.

2. The method of claim 1, wherein the base unit further includes a second circuit unit separately disposed on the insulating layer and wherein the method further comprises:
providing a first solder on the first circuit unit and a second solder on the second circuit unit;
providing an electronic element that has a first electrode and a second electrode; and
respectively disposing the first electrode and the second electrode of the electronic element on the first and second solders, such that the first electrode is electrically connected to the first circuit unit through the first solder, and the second electrode is electrically connected to the second circuit unit through the second solder.

3. The method of claim 2, further comprising the step of providing a connecting unit electrically connected to the first circuit unit and the second circuit unit for respectively and electrically connecting the first circuit unit and the second circuit unit to two terminals of a power supply.

4. The method of claim 2, wherein the electronic element is a light emitting diode, and the first and second electrodes are respectively a negative electrode that exhibits heat conducting property and a positive electrode.

5. The method of claim 2, wherein:
the electronic element is a light emitting diode, and the first and second electrodes are respectively a negative electrode and a positive electrode,
the electronic element further includes a thermal pad for heat conduction, and
the disposing step further includes disposing the thermal pad on the first solder.

6. An electronic device comprising:
a base unit that includes a metal substrate, a circuit unit and an insulating layer disposed between said metal substrate and said circuit unit, and that has a hole formed by laser ablation, said hole extending through said circuit unit and said insulating layer and terminating at and exposing said metal substrate; and
an interconnecting layer that is formed on said hole-defining wall using a metal material of said metal substrate that is ablated during laser ablation of said metal substrate, said interconnecting layer extending from said metal substrate to said circuit unit.

7. The electronic device of claim 6, further comprising an electronic element that includes an electrode electrically connected with said circuit unit.

8. The electronic device of claim 7, further comprising a solder that connects said electronic element to said circuit unit.

9. The electronic device of claim 7, wherein said metal substrate is shaped as a casing having a receiving space in which said electronic element and said circuit unit are disposed.

10. The electronic device of claim 7, wherein said electronic device is a backlight module, and said electronic element is a light source of said backlight module.
